(19) United States
(12) Patent Application Publication
(10) Pub. No.: US 2025/0192516 A1
(43) Pub. Date: Jun. 12, 2025

(54) LASER DIODE COMPONENT, LASER DIODE APPARATUS AND METHOD FOR PRODUCING A LASER DIODE COMPONENT

(71) Applicant: ams-OSRAM International GmbH, Regensburg (DE)

(72) Inventors: Sven GERHARD, Alteglofsheim (DE); Mariel Grace JAMA, Regensburg (DE)

(73) Assignee: ams-OSRAM International GmbH, Regensburg (DE)

(21) Appl. No.: 18/845,983

(22) PCT Filed: Feb. 28, 2023
(86) PCT No.: PCT/EP2023/054906

§ 371 Date: Sep. 11, 2024

(30) Foreign Application Priority Data
Mar. 15, 2022 (DE) 10 2022 106 009.8

(51) Int. Cl. H01S 5/10; H01S 5/0225; H01S 5/02315

(52) U.S. Cl. CPC H01S 5/1082; H01S 5/0225; H01S 5/02315

(57) ABSTRACT

A laser diode component is described including a semiconductor layer stack including an active zone for emitting laser radiation, a radiation exit surface, where at least a part of the laser radiation exits the semiconductor layer stack, at least one radiation exit region, where an essential part of the laser radiation is emitted and which is arranged at the radiation exit surface, and at least one projecting region and/or recessed region arranged at the radiation exit surface, wherein the at least one projecting region projects over the at least one radiation exit region in a radiation direction and the at least one recessed region is recessed with respect to the radiation exit region in the radiation direction, wherein the semiconductor layer stack comprises traces of material removal at the radiation exit surface. Moreover, a laser diode apparatus and a method for producing a laser diode component are described.

### CROSS-REFERENCE TO RELATED APPLICATIONS

The present application is a national stage entry from International Application No. PCT/EP2023/054906, filed on Feb. 28, 2023, published as International Publication No. WO 2023/174669 A1 on Sep. 21, 2023, and claims priority to German Patent Application No. 10 2022 106 009.8, filed Mar. 15, 2022, the disclosures of all of which are hereby incorporated by reference in their entireties.

### FIELD

A laser diode component, a laser diode apparatus and a method for producing a laser diode component are specified. For example, the laser diode component is suitable for heterointegration in a laser diode apparatus.

### BACKGROUND

In an exemplary method for producing edge-emitting laser chips, facets of the edge-emitting laser chips are created by breaking a wafer composite along a native crystal plane. As a result, the facet is the foremost area of the laser chip or is in the same plane as the front or back face of the laser chip. If such a laser chip is mounted on a submount, an IC (integrated circuit) or a carrier with photonic circuits, for example, it must be actively positioned with the necessary accuracy. For coupling into waveguides, for example, a correct distance of the facet to the waveguide must be taken into account. Moreover, a contact of the sensitive facet with an edge of the submount must be prevented.

One object is to specify a laser diode component providing improved reliability. This object is achieved inter alia by the laser diode component according to the independent claim. Further embodiments and further developments of the laser diode component are the subject-matter of the dependent claims.

Another object is to specify a laser diode apparatus having improved reliability. This object is achieved inter alia by the laser diode apparatus according to the independent claim. Further embodiments and further developments of the laser diode apparatus are the subject-matter of the dependent claims.

And it is a further object to specify a method for producing a laser diode component that enables simplified manufacturing. This object is achieved inter alia by the method according to the independent claim. Further embodiments and further developments of the method for producing a laser diode component are the subject-matter of the dependent claims.

### SUMMARY

According to at least one embodiment of a laser diode component, it comprises a semiconductor layer stack including an active zone for emitting laser radiation. For example, the laser diode component is suitable for emitting laser radiation having a wavelength in the visible spectral range from ultraviolet to infrared.

Moreover, the semiconductor layer stack may comprise a radiation exit surface, where at least a part of the laser radiation exits the semiconductor layer stack.

Furthermore, the semiconductor layer stack may comprise at least one radiation exit region, where an essential part of the laser radiation is emitted and which is arranged at the radiation exit surface. A surface of the at least one radiation exit region may form a planar part of the radiation exit surface.

According to at least one embodiment, the semiconductor layer stack comprises at least one projecting and/or recessed region arranged at the radiation exit surface, wherein the at least one projecting region projects over the at least one radiation exit region in a radiation direction and the at least one recessed region is recessed with respect to the radiation exit region in the radiation direction. The radiation direction may be parallel to a surface normal of the radiation exit region. The at least one projecting or recessed region may serve as spacer and/or adjustment structures, which may protect the radiation exit region from damage and/or improve the accuracy of arrangement, for example if the laser diode component is mounted on a carrier in a laser diode apparatus. Consequently, the laser diode component is provided with improved reliability by these structures. And the yield of the assembled laser diode apparatus may be higher than by active alignment.

According to at least one embodiment, the semiconductor layer stack comprises traces of material removal at the radiation exit surface. For example, when produced in a wafer composite, the radiation exit surface may be created by forming a trench at a separation plane to separate the semiconductor layer stack from the wafer composite, and thus the semiconductor layer stack comprises traces of the separation process including traces of material removal.

According to at least one embodiment of a laser diode component, it comprises:
a semiconductor layer stack comprising
   an active zone for emitting laser radiation,
   a radiation exit surface, where at least a part of the laser radiation exits the semiconductor layer stack,
   at least one radiation exit region, where an essential part of the laser radiation is emitted and which is arranged at the radiation exit surface, and
   at least one projecting region and/or recessed region arranged at the radiation exit surface, wherein the at least one projecting region projects over the at least one radiation exit region in a radiation direction and the at least one recessed region is recessed with respect to the radiation exit region in the radiation direction,
      wherein the semiconductor layer stack comprises traces of material removal at the radiation exit surface.

According to at least one embodiment or configuration, the semiconductor layer stack comprises a first semiconductor region of a first conductivity type, for example a p-doped semiconductor region, and a second semiconductor region of a second conductivity type, for example an n-doped semiconductor region.

The active zone may be arranged between the first and second semiconductor regions. The active zone may comprise a sequence of single layers which form a quantum well structure, in particular a single quantum well (SQW) structure or multiple quantum well (MQW) structure. Moreover, the first and second semiconductor regions may each have a sequence of single layers, some of which may be undoped or lightly doped.

The single layers of the semiconductor regions may be epitaxially deposited on a growth substrate.

Materials based on arsenide, phosphide or nitride compound semiconductors, for example, are suitable for the semiconductor regions or single layers of the semiconductor layer stack. “Based on arsenide, phosphide or nitride compound semiconductors” means in the present context that the semiconductor layers contain AlₙGaₘIn₁₋ₙ₋ₘAS, AlₙGaₘIn₁₋ₙ₋ₘP, InₙGa₁₋ₙASₘP₁₋ₘ or AlₙGaₘIn₁₋ₙ₋ₘN, where 0≤n≤1, 0≤m≤1 and n+m≤1. This material does not necessarily have to have a mathematically exact composition according to the above formula. Rather, it may have one or more dopants as well as additional constituents that do not substantially change the characteristic physical properties of the AlₙGaₘIn₁₋ₙ₋ₘAS, AlₙGaₘIn₁₋ₙ₋ₘP, InₙGa₁₋ₙASₘP₁₋ₘ Or AlₙGaₘIn₁₋ₙ₋ₘN material. For simplicity, however, the above formula includes only the essential constituents of the crystal lattice (Al, Ga, In, As or P or N, respectively), even though these may be partially replaced by small amounts of other substances. A quinternary semiconductor consisting of Al, Ga, In (group III) and P and As (group V) is also conceivable.

According to at least one embodiment or configuration, the at least one projecting and/or recessed region and the at least one radiation exit region comprise traces of material removal at the radiation exit surface. Especially, the traces of material removal result from a separation process, where the projecting and/or recessed region and the at least one radiation exit region are created in one step.

According to at least one embodiment or configuration, the semiconductor layer stack comprises etching traces at the radiation exit surface. In other words, the traces of material removal at the radiation exit surface may be etching traces. For example, the radiation exit surface may be created by a first etching process, for example by a dry chemical etching process, and smoothened by a second etching process, for example by a wet chemical etching process. The radiation exit surface created by etching is characterized by a small roughness, for example by a roughness smaller than 5 nm.

In contrast to a breaking process, the etching process/es allow/s for creating the at least one projecting and/or recessed region and the at least one radiation exit region in one step. The one-step process enables a high accuracy arrangement of the at least one projecting and/or recessed region in relation to the at least one radiation exit region.

According to at least one embodiment or configuration, a distance between a most distant part of the at least one projecting or recessed region and the at least one radiation exit region in the radiation direction is greater than 0 μm and smaller than 3 μm. Especially, the distance is greater than 0 nm and smaller than 300 nm. Deviations of +10% from the upper limits are possible. The projecting or recessed region serving as spacer and/or adjustment structures allow for a precise alignment of the laser diode component, ensuring small tolerances, for example when mounted on a carrier in a laser diode apparatus.

According to at least one embodiment or configuration, the semiconductor layer stack comprises a first main surface, a second main surface and at least one side face connecting the first main surface to the second main surface, wherein the radiation exit surface constitutes a side face of the semiconductor layer stack. The first main surface and the second main surface may be arranged in parallel to a main extension plane of the semiconductor layer stack. The first main surface may be arranged at a first side and the second main surface may be arranged at a second side of the laser diode component.

According to at least one embodiment or configuration, the laser diode component is an edge-emitting semiconductor laser diode, wherein the radiation exit surface of the semiconductor layer stack is arranged at a radiation exit side of the laser diode component. The radiation exit surface and a side surface of the semiconductor layer stack opposite to the radiation exit surface may constitute a laser cavity of the laser diode component. The laser diode component, especially the semiconductor layer stack, may comprise a ridge structure at the first main surface.

According to at least one embodiment or configuration, the laser diode component comprises a first reflective layer arranged on the radiation exit surface. Moreover, the laser diode component may comprise a second reflective layer arranged on the side surface of the semiconductor layer stack opposite to the radiation exit surface. The first reflective layer and the second reflective layer may constitute the laser cavity of the laser diode component. Especially, the second reflective layer has a higher reflectivity than the first reflective layer.

The first reflective layer may cover the radiation exit surface at least partly. For example, the first reflective layer covers at least the radiation exit region. Moreover, the second reflective layer may cover the corresponding side surface for the most part.

According to at least one embodiment or configuration, the first and/or second reflective layer may each comprise at least one layer of a dielectric or metal material. For example, the first and/or second reflective layer may each be a multilayer comprising at least two sublayers of different dielectric or metal materials having different refractive index or reflectivity. The first and second reflective layer may constitute a DBR (Distributed Bragg Reflector) mirror.

According to at least one embodiment or configuration, the semiconductor layer stack further comprises at least one projecting region and/or at least one recessed region at at least one surface other than the radiation exit surface. The at least one other surface may be a further side face of the semiconductor layer stack. The at least one projecting or recessed region may serve as spacer and/or adjustment structures in at least one further direction, which may run obliquely or antiparallel to the radiation direction. The further direction and the radiation direction may be essentially parallel to the main extension plane of the semiconductor layer stack. The semiconductor layer stack may comprise at least one projecting region and/or at least one recessed region at more than one surface other than the radiation exit surface.

According to at least one embodiment or configuration, the at least one projecting or recessed region has a main extension transverse to both the first and second main surfaces. A cross section of the at least one projecting or recessed region taken essentially parallel to the main extension plane may have the shape of a polygon, for example of a triangle, rectangle, trapezoid or half a hexagon. Moreover, the at least one projecting or recessed region may have the shape of a solid figure, for example of a prism.

According to at least one embodiment or configuration, surfaces of the at least one projecting or recessed region which are arranged at the radiation exit surface extend along crystal planes of the semiconductor layer stack. Besides, the surface of the radiation exit region arranged at the radiation exit surface may extend along a crystal plane of the semiconductor layer stack. For example, the crystal planes may be m-planes of the crystal of the semiconductor

layer stack. The m-plane is the-plane of a crystal with a hexagonal basic structure of the wurtzite type. Creating the surfaces of the at least one projecting or recessed region at m-planes, which are arranged at angles of 60° with respect to each other, supports cross-sectional shapes of triangles, rectangles, trapezoids or parts of hexagons.

According to at least one embodiment or configuration, the at least one radiation exit region extends from an edge of the first main surface to an edge of the second main surface or ends before the edge of the second main surface. The extension of the at least one radiation exit region in a direction pointing from the first main surface to the second main surface can be determined by an etch depth when creating the radiation exit surface.

According to at least one embodiment of a laser diode apparatus, it comprises at least one laser diode component as described above. This means that all features described in connection with the laser diode component apply to the laser diode apparatus as well, and vice versa.

The laser diode apparatus may further comprise a carrier, wherein the at least one laser diode component is arranged on the carrier.

According to at least one embodiment or configuration, the carrier comprises at least one recessed and/or projecting region complementary to the at least one projecting and/or recessed region of the at least one laser diode component, wherein the at least one projecting and/or recessed region of the at least one laser diode component engages with the at least one recessed and/or projecting region of the carrier. In this case, the at least one projecting and/or recessed region of the at least one laser diode component also serve as fixing structures fixing the laser diode component to the carrier.

According to at least one embodiment or configuration, the laser diode apparatus comprises at least one first optical element facing the radiation exit surface of the at least one laser diode component, wherein the first optical element is at least partly spaced from the radiation exit surface by a distance which is equal to or greater than a distance between the at least one projecting region and/or recessed region and the at least one radiation exit region. Especially, the distances are determined in parallel to the radiation direction. Advantageously, the at least one projecting and/or recessed region helps to align the at least one laser diode component and the at least one first optical element with respect to their mutual distance and/or their relative position. For example, the at least one first optical element is a waveguide.

According to at least one embodiment or configuration, the laser diode apparatus comprises at least one second optical element, which is arranged between the at least one radiation exit region and the at least one first optical element. For example, the second optical element is a lens.

According to at least one embodiment of a method, the method is suitable for producing a laser diode component as mentioned above. This means that all features described in connection with the laser diode component and the laser diode apparatus apply to the method as well, and vice versa.

According to at least one embodiment of the method, it comprises the following steps:
providing a semiconductor layer sequence,
creating a radiation exit surface of at least one semiconductor layer stack by forming at least one trench in the semiconductor layer sequence by a first material removal process along at least one separation plane,
smoothing the radiation exit surface of the at least one semiconductor layer stack by a second material removal process, wherein the at least one semiconductor layer stack comprises at least one projecting and/or recessed region arranged at the radiation exit surface.

The first and second material removal processes include removing material of the semiconductor layer sequence.

According to at least one embodiment or configuration, the at least one separation plane constitutes a main extension plane of the at least one trench. And the trench may separate at least two adjacent semiconductor layer stacks from each other.

According to at least one embodiment or configuration, the first and/or second material removal process is an etching process. For example, the first material removal process is a dry chemical etching process. The first material removal process may be a plasma etching process using chlorine-, boron- and argon-ions.

Moreover, the second material removal process is a wet chemical etching process. The etchant may comprise, for example, KOH, NaOH, NH4OH, LiOH, TMAH, NMP (N-methyl-2-pyrrolidone). The second material removal process may serve to prepare crystal planes as mentioned above, for example m-planes, of the semiconductor crystal. The second material removal process helps to reduce the surface roughness of the radiation exit surface. The roughness achieved in this way may be smaller than 5 nm. Moreover, the second material removal process helps to create vertically oriented surfaces running obliquely to a main extension plane of the semiconductor layer sequence or stack. Furthermore, the second material removal process allows to preserve angles of the crystal with deviations being smaller than 0.1°.

The laser diode component as well as the laser diode apparatus are suitable for AR (augmented reality) or VR (virtual reality) applications, for/as RGB projection devices, for/as integrated photonic devices and frequency doublers, for example.

Further preferred embodiments and further developments of the laser diode component, the laser diode apparatus and the method for producing a laser diode component will become apparent from the exemplary embodiments explained below in conjunction with FIGS. 1 to 20.

### BRIEF DESCRIPTION OF THE DRAWINGS

FIG. 1A shows a schematic plan view of an exemplary embodiment of a laser diode component in view of a main surface of the laser diode component,

FIG. 1B shows a schematic plan view of the laser diode component shown in FIG. 1A in view of a side face of the laser diode component, and

FIG. 1C shows a schematic plan view of an exemplary embodiment of a laser diode apparatus comprising the laser diode component shown in FIGS. 1A and 1B,

FIG. 2A shows a schematic plan view of another exemplary embodiment of a laser diode component in view of a main surface of the laser diode component,

FIG. 2B shows a schematic plan view of the laser diode component shown in FIG. 2A in view of a side face of the laser diode component, and

FIG. 2C shows a schematic plan view of another exemplary embodiment of a laser diode apparatus comprising the laser diode component shown in FIGS. 2A and 2B,

FIGS. 3 to 16 show schematic plan views of further exemplary embodiments of laser diode components,

FIGS. 17 to 19 show schematic plan views of further exemplary embodiments of laser diode apparatus,

FIG. 20A shows a schematic plan view of a wafer composite in a method stage of an exemplary embodiment of a method for producing a laser diode component before a separation step and

FIG. 20B shows a schematic plan view of the wafer composite in a method stage after the separation step.

### DETAILED DESCRIPTION

Identical, equivalent or equivalently acting elements may be indicated with the same reference numerals in the figures. The figures are schematic illustrations and thus not necessarily true to scale. Comparatively small elements and particularly layer thicknesses can rather be illustrated exaggeratedly large for the purpose of better clarification.

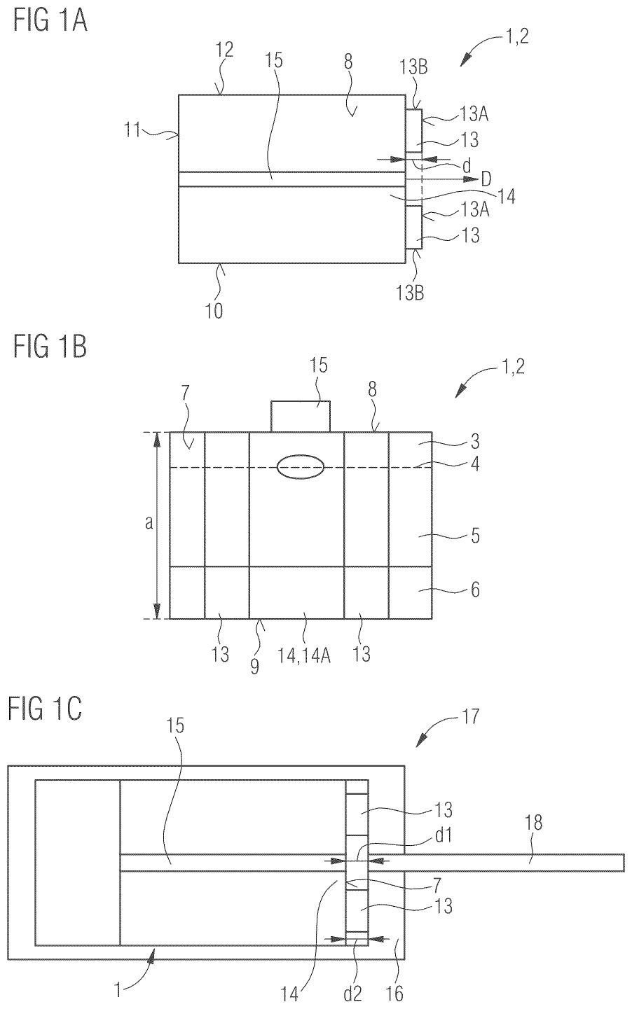

FIGS. 1A and 1B show different schematic plan views of an exemplary embodiment of a laser diode component 1.

The laser diode component 1 comprises a semiconductor layer stack 2. The laser diode component 1 may further comprise electrical contacts (not shown) for electrically contacting the semiconductor layer stack 2.

The semiconductor layer stack 2 comprises a first semiconductor region 3 of a first conductivity type, for example a p-doped semiconductor region, an active zone 4 and a second semiconductor region 5 of a second conductivity type, for example an n-doped semiconductor region, wherein the active zone 4 is arranged between the first and second semiconductor regions 3, 5. The active zone 4 may comprise a sequence of single layers which form a quantum well structure, in particular a single quantum well (SQW) structure or multiple quantum well (MQW) structure.

Moreover, the first and second semiconductor regions 3, 5 may each have a sequence of single layers, some of which may be undoped or lightly doped. The single layers of the semiconductor regions 3, 4, 5 may be epitaxially deposited on a growth substrate 6. The growth substrate 6 may remain at least partially in the laser diode component 1.

The semiconductor layer stack 2 as well as the semiconductor regions 3, 4, 5 or single layers of the semiconductor layer stack 2, may comprise materials based on arsenide, phosphide or nitride compound semiconductors as mentioned above.

The semiconductor layer stack 2 comprises a radiation exit surface 7, where at least a part of the laser radiation exits the semiconductor layer stack 2. Moreover, the semiconductor layer stack 2 comprises a first main surface 8 and a second main surface 9 opposite the first main surface 8, wherein the radiation exit surface 7 runs obliquely to each of the first and second main surfaces 8, 9. The first main surface 8 and the second main surface 9 are arranged essentially parallel to a main extension plane of the semiconductor layer stack 2.

Furthermore, the semiconductor layer stack 2 comprises several side faces 10, 11, 12 connecting the first main surface 8 to the second main surface 9 and running obliquely to each of the first and second main surfaces 8, 9. The radiation exit surface 7 constitutes one of the side faces of the semiconductor layer stack 2.

The semiconductor layer stack 2 comprises projecting regions 13 arranged at the radiation exit surface 7, wherein surfaces 13A, 13B of the projecting regions 13 form a part of the radiation exit surface 7. The projecting regions 13 each have a main extension transverse to both the first and second main surfaces 8, 9. The projecting regions 13 each have a rectangular cross-sectional shape (see FIG. 1A) and a three-dimensional prism-like shape (see FIGS. 1A and 1B).

Moreover, the semiconductor layer stack 2 comprises a radiation exit region 14 arranged between the projecting regions 13. A surface 14A of the radiation exit region 14 forms a planar part of the radiation exit surface 7.

Both the projecting regions 13 and the radiation exit region 14 have an extension a ranging from an edge of the first main surface 8 to an edge of the second main surface 9.

Especially, the surfaces 13A, 13B of the projecting regions 13 extend along crystal planes of the semiconductor layer stack 2. And the surface 14A of the radiation exit region 14 may extend along a crystal plane of the semiconductor layer stack 2 as well. For example, the crystal planes may be m-planes of the crystal of the semiconductor layer stack 2. The m-plane is the-plane of a crystal with a hexagonal basic structure of the wurtzite type. Creating the surfaces 13A, 13B, 14A at m-planes, which are arranged at angles of 60° with respect to each other, supports cross-sectional shapes of triangles, rectangles, trapezoids or parts of hexagons.

During operation, the active zone 4 may emit laser radiation at the radiation exit surface 7, where an essential part of the laser radiation is emitted in the radiation exit region 14 (see elliptical area in FIG. 1B). Advantageously, the projecting regions 13 are adjacent to the radiation exit region 14 so that a disruption of the laser beam can be minimized. The radiation is emitted in a radiation direction D, which is essentially parallel to a surface normal of the radiation exit region 14 or its surface 14A.

The projecting regions 13 each project over the radiation exit region 14 in the radiation direction D. The projecting regions 13 may serve as spacer and/or adjustment structures, which may protect the radiation exit region 14 from damage and/or improve the accuracy of arrangement, for example if the laser diode component 1 is mounted on a carrier 16 (see FIG. 1C). Consequently, the laser diode component 1 is provided with improved reliability by these structures 13.

For example, a distance d between a most distant part of each of the projecting regions 13 and the radiation exit region 14 in the radiation direction D is greater than 0 μm and smaller than 3 μm. Especially, the distance d is greater than 0 nm and smaller than 300 nm. Deviations of +10% from the upper limits are possible.

The laser diode component 1 may be an edge-emitting laser diode, where the radiation exit surface 7 and the side face 11 opposite to the radiation exit surface 7 may constitute a laser cavity of the laser diode component 1. The laser diode component 1, especially the semiconductor layer stack 2, comprises a ridge structure 15 at the first main surface 8 for carrier confinement.

For example, the active zone 4 or laser diode component 1 is suitable for emitting laser radiation having a wavelength in the visible spectral range from ultraviolet to infrared.

The semiconductor layer stack 2 comprises traces of material removal at the radiation exit surface 7 (not shown). Especially, the traces of material removal are an indication of a separation process the semiconductor layer stack 2 undergoes during manufacturing. For example, when produced in a wafer composite, the radiation exit surface 7 may be created by forming a trench at a separation plane to separate the semiconductor layer stack 2 from the wafer composite, and thus the semiconductor layer stack 2 comprises traces of the separation process including traces of material removal. Both the projecting regions 13 and the radiation exit region 14 may comprise traces of material removal at the radiation exit surface 7. Especially, the traces of material removal result from a separation process, where the projecting regions 13 and the radiation exit region 14 are created together in one step. Advantageously, the one-step production enables a high accuracy arrangement of the projecting regions 13 in relation to the radiation exit region 14.

Especially, the traces of material removal are etching traces. For example, the radiation exit surface 7 is created by a first etching process, for example by a dry chemical etching process, and smoothened by a second etching process, for example by a wet chemical etching process. The radiation exit surface 7 created by etching is characterized by a small roughness, for example by a roughness smaller than 5 nm.

FIG. 1C shows a schematic plan view of a laser diode apparatus 17 comprising a laser diode component 1 as described in connection with FIGS. 1A and 1B and a carrier 16, wherein the laser diode component 1 is arranged on the carrier 16.

The laser diode apparatus 17 further comprises an optical element 18 facing the radiation exit surface 7 of the laser diode component 1. The optical element 18 is a waveguide, for example. In particular, a distance d1 between the radiation exit region 14 and the optical element 18 is equal to or greater than a distance d2 between a most distant part of each of the projecting regions 13 and the radiation exit region 14. In other words, the optical element 18 is spaced apart from the radiation exit region 14 at least by a maximum projection of the projecting regions 13 over the radiation exit region 14. Advantageously, the projecting regions 13 serving as spacer structures help to prevent a contact of the sensitive radiation exit region 14 with an edge of the carrier 16 or with the optical element 18. Moreover, the projecting regions 13 help to align the laser diode component 1 to the optical element 18 with respect to mutual distance and/or relative position.

In addition, the laser diode component 1 and the laser diode apparatus 17 may have any of the features, characteristics and advantages mentioned in connection with the further exemplary embodiments.

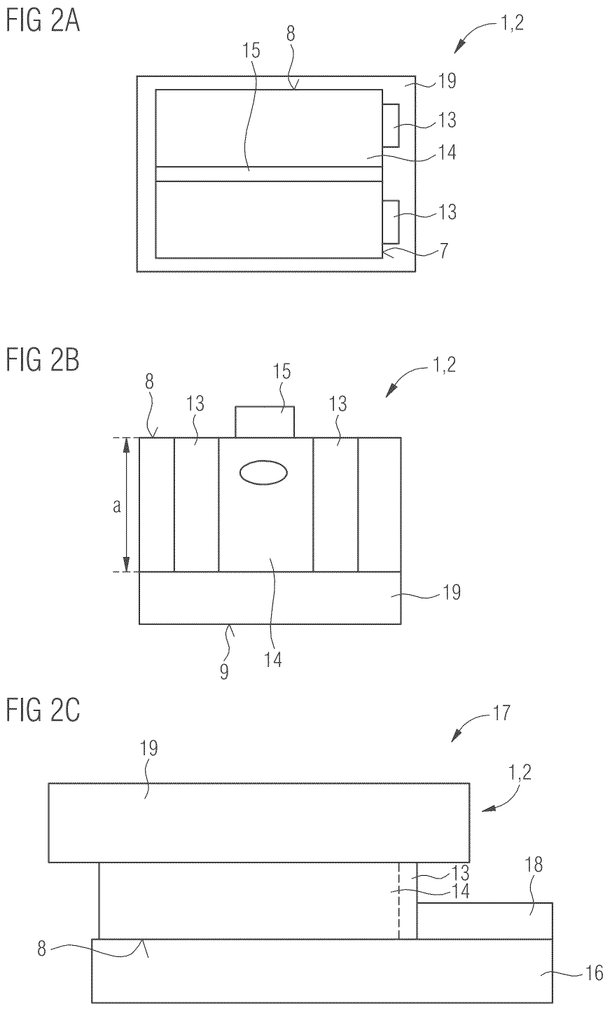

FIGS. 2A and 2B show another exemplary embodiment of a laser diode component 1. The laser diode component 1 comprises a semiconductor layer stack 2 including a radiation exit region 14 at a radiation exit surface 7. The radiation exit region 14 extends from an edge of a first main surface 8 in a direction pointing from the first main surface 8 to a second main surface 9 and ends before an edge of the second main surface 9, leaving a remainder region 19. An extension a of the radiation exit region 14 in the direction pointing from the first main surface 8 to the second main surface 9 can be determined by an etch depth when creating the radiation exit surface 7.

While the extension a or etch depth in the exemplary embodiment of FIGS. 1A and 1B is larger than in the exemplary embodiment of FIGS. 2A and 2B and can be realized, for example, by forming an etching trench 25 (see FIG. 20B) over a large depth from a first side of the wafer and then thinning the wafer from a second side by grinding or polishing, for example, so that one thins to the depth of the trench (so-called Dicing Before Grinding (DBG)), it is also possible to etch the trench to a lesser depth. In this case, a remainder region 19 is left after the components have been separated (see FIGS. 2A to 2C).

In a laser diode apparatus 17 as shown in FIG. 2C, comprising a carrier 16 and a laser diode component 1 as described in connection with FIGS. 2A and 2B, the laser diode component 1 is mounted on the carrier 16 with its first main surface 8 such that the remainder region 19 of the semiconductor layer stack 2 is arranged on a side of the laser diode component 1 facing away from the carrier 16. An optical element 18, for example a waveguide, is arranged below the remainder region 19 on the carrier 16, facing the radiation exit region 14 of the semiconductor layer stack 2. Thus, the remainder region 19 does not limit the laser beam.

In addition, the laser diode component 1 and the laser diode apparatus 17 may have any of the features, characteristics and advantages mentioned in connection with the further exemplary embodiments.

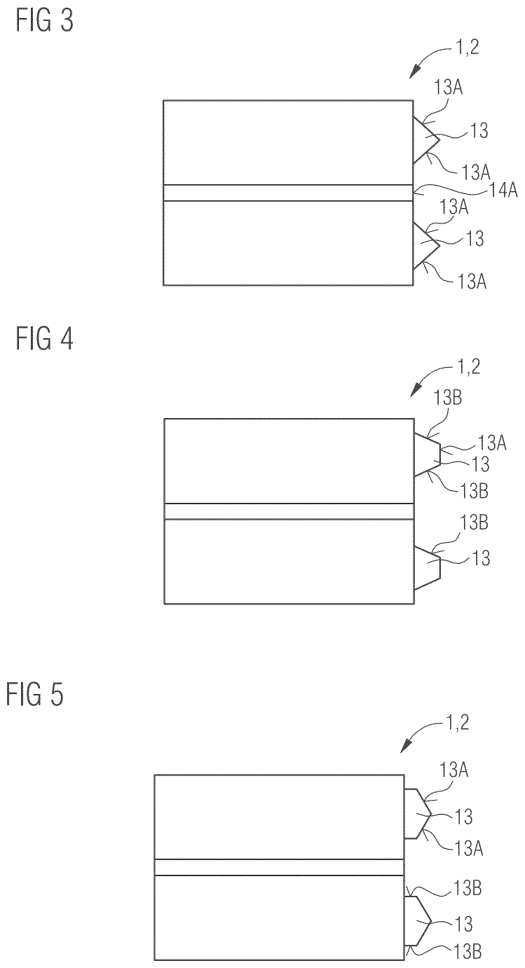

In FIGS. 3 to 5, further designs of the projecting regions 13 are illustrated. The projecting regions 13 of these exemplary embodiments have in common that they have a prism-like shape. However, their cross-sectional views parallel to main extension planes of the laser diode components 1 is different. In the laser diode component 1 shown in FIG. 3, the projecting regions 13 each have a triangular cross-sectional shape. In the laser diode component 1 shown in FIG. 4, the projecting regions 13 each have a trapezoid cross-sectional shape. In the laser diode component 1 shown in FIG. 5, the projecting regions 13 each have a cross-sectional shape corresponding to half a hexagon. As mentioned above, creating the surfaces 13A, 13B, 14A at m-planes, which are arranged at angles of 60° with respect to each other, supports cross-sectional shapes of triangles, rectangles, trapezoids or parts of hexagons.

In addition, the laser diode components 1 may have any of the features, characteristics and advantages mentioned in connection with the further exemplary embodiments.

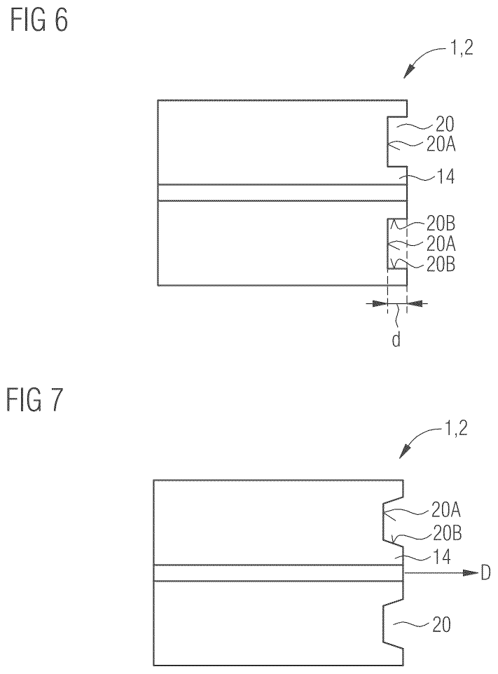

In FIGS. 6 and 7, further exemplary embodiments of laser diode components 1 are illustrated. In these exemplary embodiments, the semiconductor layer stacks 2 each comprise recessed regions 20 instead of projecting regions. As shown in FIG. 6, the recessed regions 20 may each have a rectangular cross-sectional shape. As shown in FIG. 7, the recessed regions 20 may each have a trapezoid cross-sectional shape. As mentioned in connection with the projecting regions, other shapes like triangles or parts of hexagons are possible, too.

The recessed regions 20 are each recessed with respect to a radiation exit region 14 in a radiation direction D. Thus, the laser beam may be less affected than in the case of projecting regions. For example, a distance d between a most distant part of each of the recessed regions 20 and the radiation exit region 14 in the radiation direction D is greater than 0 μm and smaller than 3 μm. Especially, the distance d is greater than 0 nm and smaller than 300 nm. Deviations of +10% from the upper limits are possible. The recessed regions 20 may serve as adjustment structures, which improve the accuracy of arrangement, for example if the laser diode component 1 is mounted on a carrier in a laser diode apparatus. Consequently, the laser diode component 1 is provided with improved reliability by these structures 20. And the yield of the assembled laser diode apparatus may be higher than by active alignment.

In addition, the laser diode components 1 may have any of the features, characteristics and advantages mentioned in connection with the further exemplary embodiments.

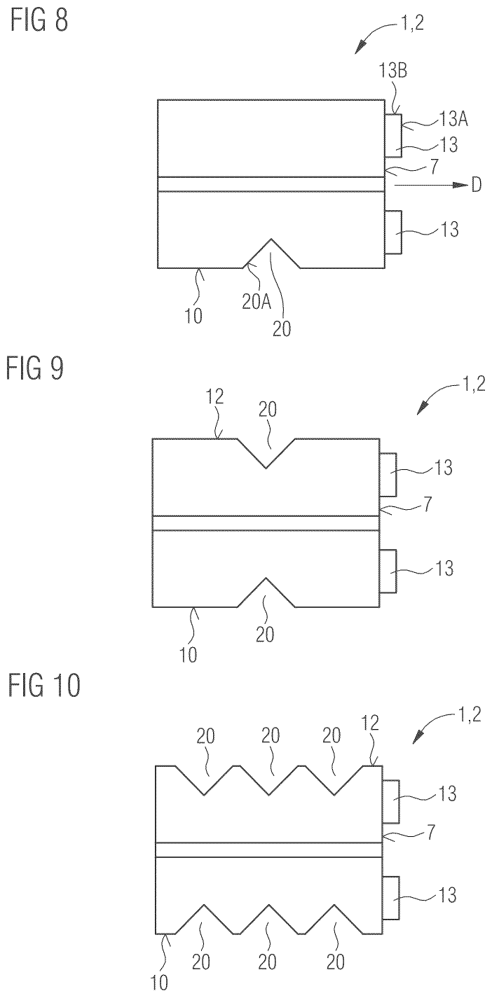

In FIGS. 8 to 12, further exemplary embodiments of laser diode components 1 are illustrated. The laser diode components 1 have in common that their semiconductor layer stacks 2 each comprise at least one additional projecting region 13 or recessed region 20 at at least one surface other than the radiation exit surface 7. For example, the other surface/s is/are side faces 10, 11, 12 of the semiconductor layer stacks 2.

In the laser diode component 1 shown in FIG. 8, the semiconductor layer stack 2 comprises a recessed region 20 having a triangular cross-sectional shape at the side face 10 adjoining the radiation exit surface 7 and running obliquely thereto.

In the laser diode component 1 shown in FIG. 9, the semiconductor layer stack 2 comprises a recessed region 20 having a triangular cross-sectional shape at each of the two side faces 10, 12, which each adjoin the radiation exit surface 7 and run obliquely thereto.

In the laser diode component 1 shown in FIG. 10, the semiconductor layer stack 2 comprises several recessed regions 20 having a triangular cross-sectional shape at each of the two side faces 10, 12, which each adjoin the radiation exit surface 7 and run obliquely thereto.

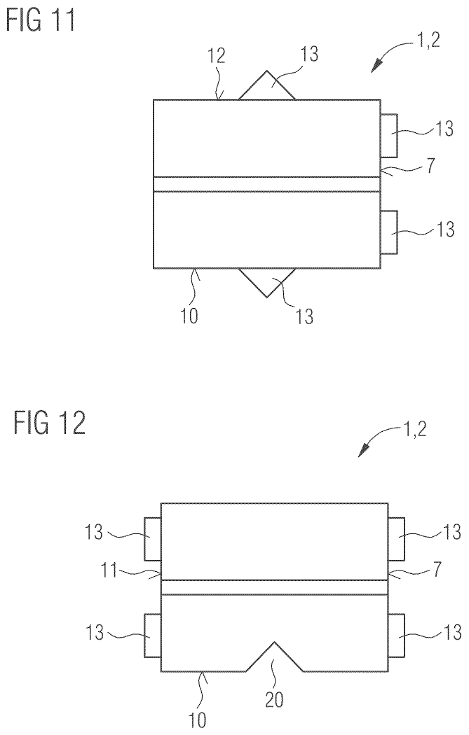

In the laser diode component 1 shown in FIG. 11, the semiconductor layer stack 2 comprises projecting regions 13 having a triangular cross-sectional shape, each of which is arranged at one of the two side faces 10, 12, which each adjoin the radiation exit surface 7 and run obliquely thereto.

In the laser diode component 1 shown in FIG. 12, the semiconductor layer stack 2 comprises a recessed region 20 having a triangular cross-sectional shape at the side face 10 adjoining the radiation exit surface 7 and running obliquely thereto. Moreover, the semiconductor layer stack 2 comprises two projecting regions 13 at the side face 11 opposite the radiation exit surface 7.

The at least one additional projecting or recessed region 13, 20 may serve as spacer and/or adjustment structures in at least one further direction, which runs obliquely or antiparallel to the radiation direction D.

Especially, the at least one additional projecting or recessed regions 13, 20 are created as mentioned in connection with the projecting and recessed regions 13, 20 at the radiation exit surface 7. Especially, surfaces 13A, 13B, 20A of the at least one projecting or recessed region 13, 20 extend along crystal planes of the semiconductor layer stacks 2.

In addition, the laser diode components 1 may have any of the features, characteristics and advantages mentioned in connection with the further exemplary embodiments.

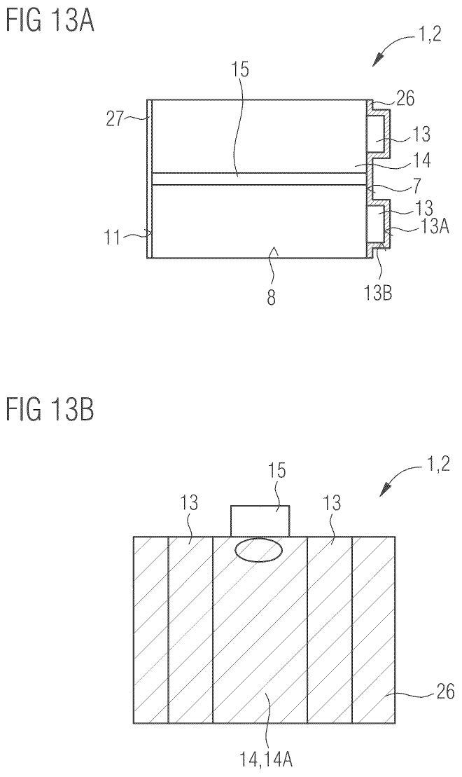

In FIGS. 13 to 16, further exemplary embodiments of laser diode components 1 are illustrated, which each comprise a first reflective layer 26 and a second reflective layer 27, wherein the first reflective layer 26 is arranged on the radiation exit surface 7 and the second reflective layer 27 is arranged on the side surface 11 opposite to the radiation exit surface 7. The second reflective layer 27 covers the side surface 11 for the most part. The first and second reflective layers 26, 27 form a laser cavity of the laser diode component 1.

Especially, the second reflective layer 27 has a higher reflectivity than the first reflective layer 26. The first and/or second reflective layer 26, 27 may each comprise at least one layer of a dielectric or metal material. For example, the first and/or second reflective 26, 27 layer may each be a multilayer comprising at least two sublayers of different dielectric or metal materials having different refractive index or reflectivity. The first and second reflective layer 26, 27 may constitute a DBR (Distributed Bragg Reflector) mirror.

In the laser diode component 1 shown in FIG. 13A (schematic plan view in view of the main surface 8) and FIG. 13B (schematic plan view in view of the radiation exit surface 7), the first reflective layer 26 completely covers the radiation exit surface 7 including the surfaces 13A, 13B of the projecting regions 13 and the surface 14A of the radiation exit region 14.

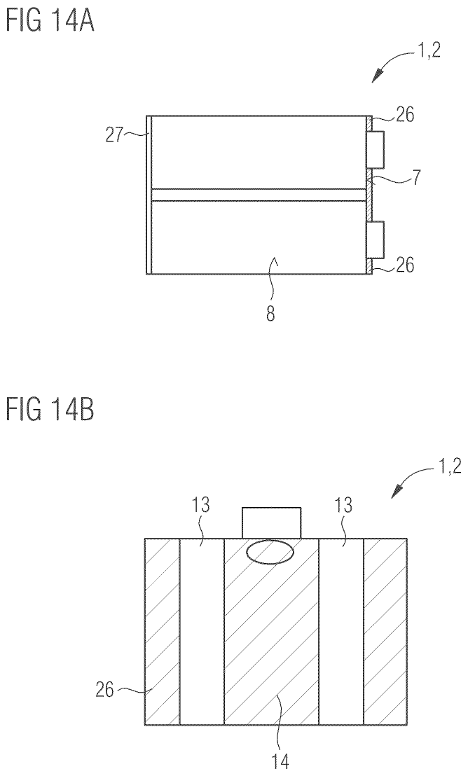

In the laser diode component 1 shown in FIG. 14A (schematic plan view in view of the main surface 8) and FIG. 14B (schematic plan view in view of the radiation exit surface 7), the first reflective layer 26 partly covers the radiation exit surface 7, wherein only the projecting regions 13 are uncovered by the first reflective layer 26.

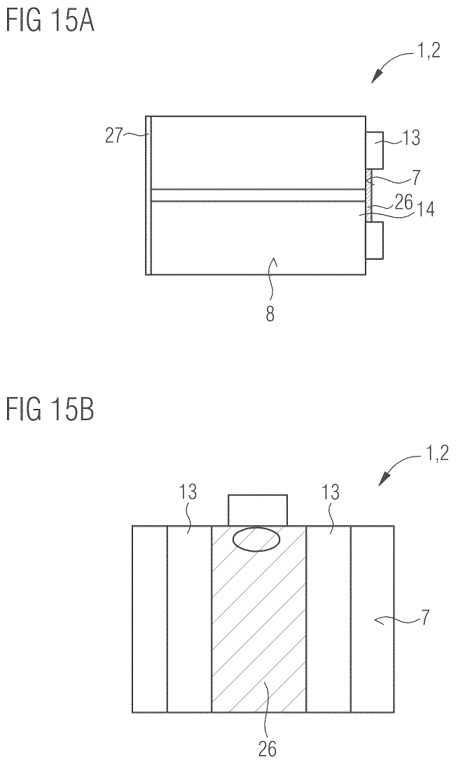

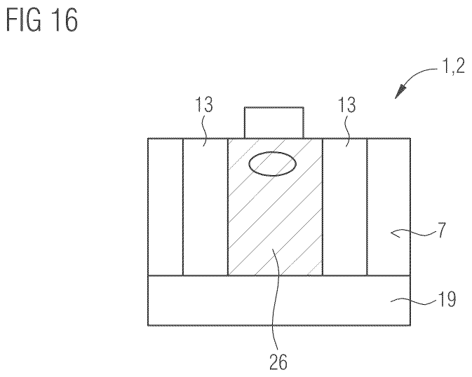

In the laser diode component 1 shown in FIG. 15A (schematic plan view in view of the main surface 8) and FIG. 15B (schematic plan view in view of the radiation exit surface 7) as well as in FIG. 16 (schematic plan view in view of the radiation exit surface 7), the first reflective layer 26 partly covers the radiation exit surface 7, wherein only the radiation exit region 14 is covered by the first reflective layer 26.

In addition, the laser diode components 1 may have any of the features, characteristics and advantages mentioned in connection with the further exemplary embodiments.

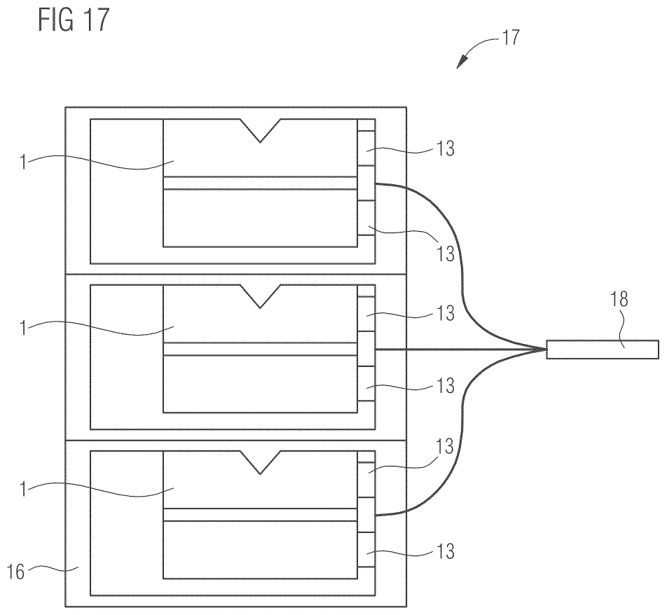

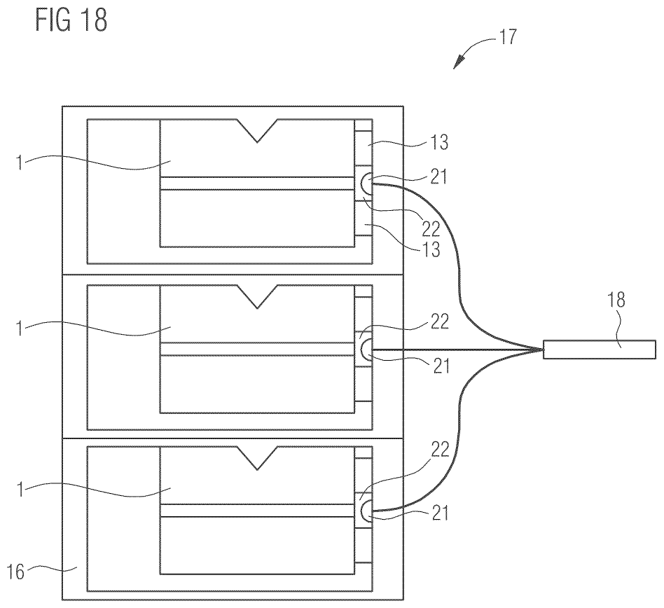

FIGS. 17 and 18 show further exemplary embodiments of laser diode apparatus 17. The laser diode apparatus 17 each comprise several laser diode components 1 arranged on a common carrier 16, wherein the laser diode components 1 comprise projecting structures 13.

The laser diode components 1 included in one laser diode apparatus 17 emit different colored light, for example red, green and blue light. Their light may be combined by a first optical element 18, which is a beam combiner, for example.

As shown in FIG. 18, the laser diode apparatus 17 may comprise several second optical elements 21, which are lenses, for example, wherein one second optical element 21 is assigned to one laser diode component 1. The second optical elements 21 are arranged in interspaces 22 existing between projecting portions 13 of each laser diode component 1.

By means of the projecting portions 13, an optimal distance can be achieved between the second optical element 21 and the radiation exit region 14 assigned thereto.

The laser diode apparatus 17 of FIGS. 17 and 18 may each constitute a full color layer light source.

In addition, the laser diode components 1 and laser diode apparatus 17 may have any of the features, characteristics and advantages mentioned in connection with the further exemplary embodiments.

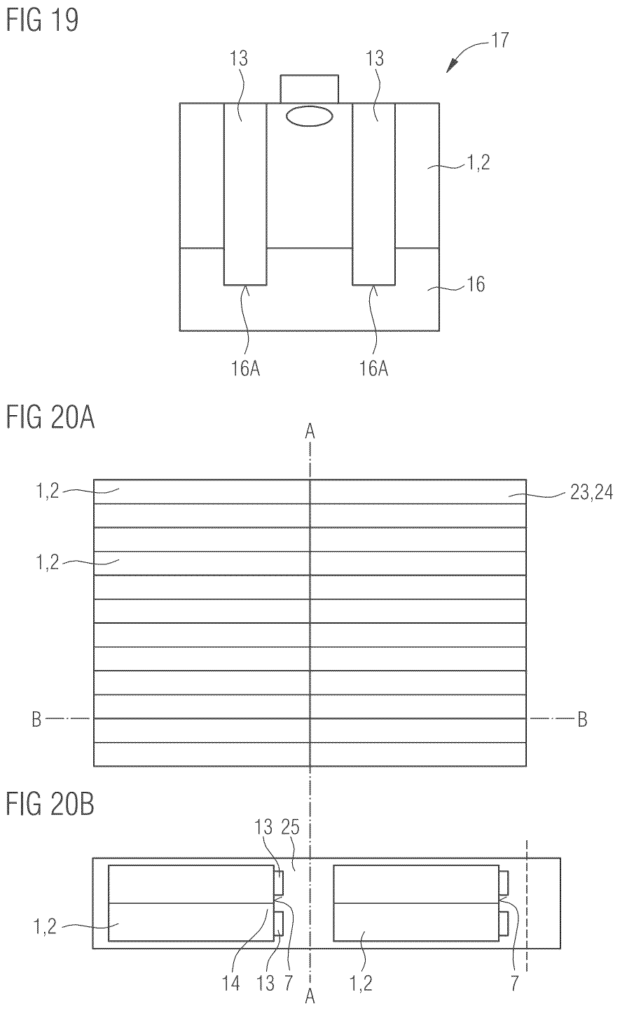

FIG. 19 shows a further exemplary embodiment of a laser diode apparatus 17. The laser diode apparatus 17 comprises a laser diode component 1, for example as described in connection with FIGS. 1A and 1B, and a carrier 16, where the laser diode component 1 is mounted. The carrier 16 comprises recessed regions 16A complementary to the projecting regions 13 of the laser diode component 1, wherein the projecting regions 13 each engage with one of the recessed regions 16A of the carrier 16. In this case, the projecting regions 13 also serve as fixing structures fixing the laser diode component 1 to the carrier 16.

Additionally or alternatively, the carrier 16 may comprise projecting regions, where recessed regions of the laser diode component 1 engage.

In addition, the laser diode component 1 and laser diode apparatus 17 may have any of the features, characteristics and advantages mentioned in connection with the further exemplary embodiments.

An exemplary embodiment of a method for producing a laser diode component 1, for example as specified in connection with FIGS. 1A and 1B, is described by FIGS. 20A and 20B.

The method comprises providing a semiconductor layer sequence 23. For example, the semiconductor layer sequence 23 is part of a wafer composite 24 further comprising a growth substrate, where the semiconductor layer sequence 23 is deposited. The semiconductor layer sequence 23 or wafer composite 24 may be separated along at least one first separation plane A-A and along at least one second separation plane B-B in order to produce a plurality of semiconductor layer stacks 2 or laser diode components 1 (see FIG. 20A). The at least one first separation plane A-A and the at least one second separation plane B-B run obliquely, for example perpendicularly, to each other.

The method comprises creating a radiation exit surface 7 of at least one semiconductor layer stack 2 by forming at least one trench 25 in the semiconductor layer sequence 23 or wafer composite 24 by a first material removal process along the at least one first separation plane A-A, wherein the at least one semiconductor layer stack 2 comprises projecting regions 13 arranged at the radiation exit surface 7. Especially, the at least one first separation plane A-A constitutes a main extension plane of the at least one trench 25.

The at least one trench 25 may have a cross-section transverse to the at least one first separation plane A-A which has a shape deviating from a rectangle. For example, an edge of the at least one trench 25 may have projecting and recessed portions. The at least one trench 25 may separate at least two adjacent semiconductor layer stacks 2 from each other.

A mask layer may be used on the semiconductor layer sequence 23 or wafer composite 24 for defining the at least one trench 25 (not shown).

The method further comprises smoothing the radiation exit surface 7 of the at least one semiconductor layer stack 2 by a second material removal process.

The first and second material removal processes include removing material of the semiconductor layer sequence 23.

Moreover, at least one trench may be produced along the second separation plane B-B to separate at least two adjacent semiconductor layer stacks 2 from each other (not shown). The at least one trench may be etched into the semiconductor layer sequence 23 or wafer composite 24.

Preferably, the first and second material removal processes are etching processes. By creating the radiation exit surface 7 by means of etching it is possible to retract a part of the radiation exit surface 7 from the first separation plane A-A in a predetermined way and to precisely define a distance between a most distant part of the retracted part (here the radiation exit region 14) and a non-or less retracted part (here the projecting regions 13). However, when the radiation exit surface 7 is created by breaking, for example, it is planar and oriented along the at least one first separation plane A-A.

For example, the first material removal process is a dry chemical etching process. The first material removal process may be a plasma etching process using chlorine-, boron- and argon-ions. And the second material removal process is a wet chemical etching process, for example. The etchant may comprise, for example, KOH, NaOH, NH₄OH, LiOH, TMAH, NMP (N-methyl-2-pyrrolidone).

The second material removal process especially serves to prepare crystal planes, for example m-planes, of the semiconductor crystal of the semiconductor layer sequence 23 or semiconductor layer stack 2. The second material removal process helps to reduce the surface roughness of the radiation exit surface 7. The roughness achieved in this way may be smaller than 5 nm. Moreover, the second material removal process helps to create vertically oriented surfaces running obliquely to a main extension plane of the semiconductor layer sequence 23 or stack 2. Furthermore, the second material removal process allows to preserve angles of the crystal with deviations being smaller than 0.1°.

In addition, the method used for producing laser diode components 1 may have any of the features, characteristics and advantages mentioned in connection with the further exemplary embodiments.

The invention is not limited to these embodiments by the description based on the embodiments. Rather, the invention includes any new feature and any combination of features, which includes in particular any combination of features in the patent claims, even if this feature or this combination itself is not explicitly indicated in the patent claims or embodiments.

1. A laser diode component comprising:
a semiconductor layer stack comprising:
an active zone for emitting laser radiation,
a radiation exit surface, where at least a part of the laser radiation exits the semiconductor layer stack, wherein the semiconductor layer stack comprises traces of material removal at the radiation exit surface,
at least one radiation exit region, where an essential part of the laser radiation is emitted and which is arranged at the radiation exit surface, and
at least one projecting region and/or recessed region arranged at the radiation exit surface, wherein the at least one projecting region projects over the at least one radiation exit region in a radiation direction and the at least one recessed region is recessed with respect to the radiation exit region in the radiation direction, and wherein the at least one projecting region and/or recessed region and the at least one radiation exit region comprise traces of material removal at the radiation exit surface.

2. The laser diode component according to claim 1, wherein the semiconductor layer stack comprises etching traces at the radiation exit surface.

3. The laser diode component according to claim 1, wherein a distance between a most distant part of the at least one projecting region or recessed region and the at least one radiation exit region in the radiation direction is greater than 0 μm and smaller than 3 μm.

4. The laser diode component according to claim 1, wherein the semiconductor layer stack further comprises at least one projecting region and/or at least one recessed region at at least one surface other than the radiation exit surface.

5. The laser diode component according to claim 1, wherein the semiconductor layer stack comprises a first main surface, a second main surface and at least one side face connecting the first main surface to the second main surface, wherein the radiation exit surface constitutes a side face of the semiconductor layer stack.

6. The laser diode component according to claim 5, wherein the at least one projecting region or recessed region has a main extension transverse to both the first and second main surfaces.

7. The laser diode component according to claim 5, wherein the at least one radiation exit region extends from an edge of the first main surface to an edge of the second main surface or ends before the edge of the second main surface.

8. The laser diode component according to claim 1, wherein surfaces of the at least one projecting region or recessed region, which are arranged at the radiation exit surface, extend along crystal planes of the semiconductor layer stack.

9. A laser diode apparatus comprising:
at least one laser diode component according to claim 1, and
a carrier, wherein
the at least one laser diode component is arranged on the carrier.

10. The laser diode component according to claim 9,
wherein the carrier comprises at least one recessed region and/or projecting region complementary to the at least one projecting region and/or recessed region of the at least one laser diode component, and
wherein the at least one projecting region and/or recessed region of the at least one laser diode component engages with the at least one recessed region and/or projecting region of the carrier.

11. The laser diode component according to claim 9, comprising at least one first optical element facing the radiation exit surface of the at least one laser diode component, wherein the first optical element is at least partly spaced from the radiation exit surface by a distance which is equal to or greater than a distance between a most distant part of the at least one projecting region and/or recessed region and the at least one radiation exit region.

12. The laser diode component according to claim 11, comprising at least one second optical element, which is arranged between the at least one radiation exit region and the at least one first optical element.

13. A method for producing a laser diode component according to claim 1, comprising:
providing a semiconductor layer sequence,
creating a radiation exit surface of at least one semiconductor layer stack by forming at least one trench in the semiconductor layer sequence by a first material removal process along at least one separation plane, and
smoothing the radiation exit surface of the at least one semiconductor layer stack by a second material removal process,
wherein the at least one semiconductor layer stack comprises at least one projecting region and/or recessed region arranged at the radiation exit surface.

14. The method according to claim 13, wherein the first and/or second material removal process is an etching process.

15. The method according to claim 13, wherein the first material removal process is a dry chemical etching process.

16. The method according to claim 13, wherein the second material removal process is a wet chemical etching process.

17. A laser diode component comprising:
a semiconductor layer stack comprising,
an active zone for emitting laser radiation,
a radiation exit surface, where at least a part of the laser radiation exits the semiconductor layer stack, wherein the semiconductor layer stack comprises traces of material removal at the radiation exit surface,
a first main surface, a second main surface and at least one side face connecting the first main surface to the second main surface, wherein the radiation exit surface constitutes a side face of the semiconductor layer stack,
at least one radiation exit region, where an essential part of the laser radiation is emitted and which is arranged at the radiation exit surface, and
at least one projecting region and/or recessed region arranged at the radiation exit surface,
wherein the at least one projecting region projects over the at least one radiation exit region in a radiation direction and the at least one recessed region is recessed with respect to the radiation exit region in the radiation direction,
wherein the at least one projecting region and/or recessed region and the at least one radiation exit region comprise traces of material removal at the radiation exit surface,
wherein the at least one projecting region or recessed region has a main extension transverse to both the first and second main surfaces and
wherein at least one of the at least one projecting region and/or recessed region, which is closest to the radiation exit region, is a recessed region.
